(19) United States
(12) Patent Application Publication
(10) Pub. No.: US 2008/0144860 A1
(43) Pub. Date: Jun. 19, 2008

(54) Adjustable Resolution Volume Control

(76) Inventors: Dennis Haller, Burnaby (CA); Joanna Zander, North Vancouver (CA); Ivy Yin, Richmond (CA); Renata Jurica, Vancouver (CA)

Correspondence Address: BANNER & WITCOFF, LTD., TEN SOUTH WACKER DRIVE, SUITE 3000, CHICAGO, IL, 60606, US

(21) Appl. No.: 11/611,381

(22) Filed: Dec. 15, 2006

(51) Int. Cl. H03G 3/00; H04R 1/02

(52) U.S. Cl. 381/109; 381/104; 381/335; 700/94

(57) ABSTRACT

A portable device includes a plurality of audio hardware outputs that may have different ranges of audio output levels associated with each of the hardware outputs. The portable device further includes two software applications that may have different volume control schemes. A check is made to determine what hardware output is being used and which software application is being used to generate audible output. The hardware and software levels are automatically mapped together and controlled so that a user may use a single volume control user interface to adjust the volume regardless of the software application or hardware output that is selected.

### BACKGROUND OF THE INVENTION

1. Field of the Invention

The present invention relates to the field of media devices, more particularly to the field of media devices that are portable and include outputs for audio.

2. Description of Related Art

Portable devices such as cellular phones commonly include a volume control so that the user can adjust the audio output according to environmental conditions and user preference. Often the current volume is graphically displayed if the user makes a change the volume setting so that use can receive audible as well as visual clues as to the change in volume setting.

While this has proven useful for devices that have a single use, such a cellular phone that does not have any capabilities other than making phone calls, portable devices such as cellular phones are beginning to be used for a number of different functions. For example, a cellular phone could be used to make phone calls, play music, watch television in a live manner, play games developed for such a device, purchase goods and services, obtain directions as well as numerous other uses that have become possible with the increased processing power, high speed networks and increased available memory that allows greater functionality to be provided by the portable device. Thus, portable devices have begun to be used for a wide number of different functions.

While users generally enjoy the additional capabilities provided, one issue that has arisen is that the users need to control the different software that provides the different functions. For example, one software application might be used to provide cellular service while another software application could be used to provide music playback. Given the possibility for a number of different applications residing on a portable device, a system for making it easier for the user to control certain functions would be beneficial.

### BRIEF SUMMARY OF THE INVENTION

A portable device includes two different audio hardware outputs that may have two different ranges of audio output levels associated with each of the two hardware outputs. The portable device further includes two software applications that may have different volume control schemes. A check is made to determine what hardware output is being used and which software application is being used to generate audible output. The hardware and software levels are mapped together and controlled so that a user may use a single volume control user interface to adjust the volume regardless of the software application or hardware output that is being used. A graphical display of the current volume may be adjusted so that the user perceives a number of volume steps are available even if the hardware output is capable of some greater number of volume levels.

This summary is provided to introduce a selection of concepts in a simplified form that are further described below in the Detailed Description. The Summary is not intended to identify key features or essential features of the claimed subject matter, nor is it intended to be used to limit the scope of the claimed subject matter.

### BRIEF DESCRIPTION OF THE DRAWINGS

The present invention is illustrated by way of example and not limited in the accompanying figures in which like reference numerals indicate similar elements and in which:

FIG. 1 illustrates a schematic of an embodiment of a portable device that may be used in accordance with one or more aspects of the present invention.

FIG. 2 illustrates a schematic of an embodiment of a portable device that may be used in accordance with one or more aspects of the present invention.

FIG. 3 illustrates a method of determining the number of volume steps to provide to a user that may be used in accordance with one or more aspects of the present invention.

FIG. 4 illustrates a method of mapping volume steps in software with gain levels in hardware that may be used in accordance with one or more aspects of the present invention.

FIGS. 5-6 illustrate graphical representations of mappings between hardware, software applications and graphic displays that may be used in accordance with one or more aspects of the present invention.

### DETAILED DESCRIPTION OF THE INVENTION

Adjusting the volume on a hand-held device is generally a straight forward task. Often a user input such as button, switch, touch-sensitive pad or joystick like device can be actuated so that volume is raised or lowered. However, when the portable device is used for multiple purposes, it can be more difficult to change the volume. For example, a user listening to music with headphones may desire to have a fairly large number of output levels so that the volume can be turned to the desired output level, depending on the music and the desire to block out noises from the surrounding environment. However, if the same device also works as a phone, the user may want to quickly adjust the volume of the phone. Thus, having a large number of volume steps would be less desirable. This is further complicated if the portable device has multiple audio hardware outputs such as speakers or headphone jacks. For example, if the user is using headphones then finer grain control of the volume is useful. However, if external speakers on the device are being used, then it may more helpful to have an adjustment in volume provide a relatively larger change in the volume. For example, in an embodiment that included a portable cellular phone with music playing abilities, it might be suitable to have ten volume increments when a telephone call is being made over a earpiece or headset, to have twenty volume increments when music is being played via headphones, to have ten volume increments when music is being played over external speaker of the cellular phone and to have fifteen volume increments when music is being played over a Bluetooth headset. In addition, as certain headsets have multiple uses such as acting as both a telephone headset and headphones, when the user switched between software applications, the desired number of steps would change. Therefore, it would be helpful if a number of available steps of volume could be adjusted depending on the software application being used to generate the audio output as well as the hardware output being used.

Before discussing additional details of depicted embodiments, it should be noted that many physical components can be divided into a number of discrete components that when combined provide the desired functionality. Thus, the combination of the components provides a module with desired functionality. For ease of discussion, therefore, the phrase module is used herein to refer to one or more components that are used to provide the desired function. For example, a CPU module refers to one or more logical processors that when used, alone or in combination with other logical processors, provides the functionality associated with a processing unit such as a general purpose computer or a digital signal processor or the like.

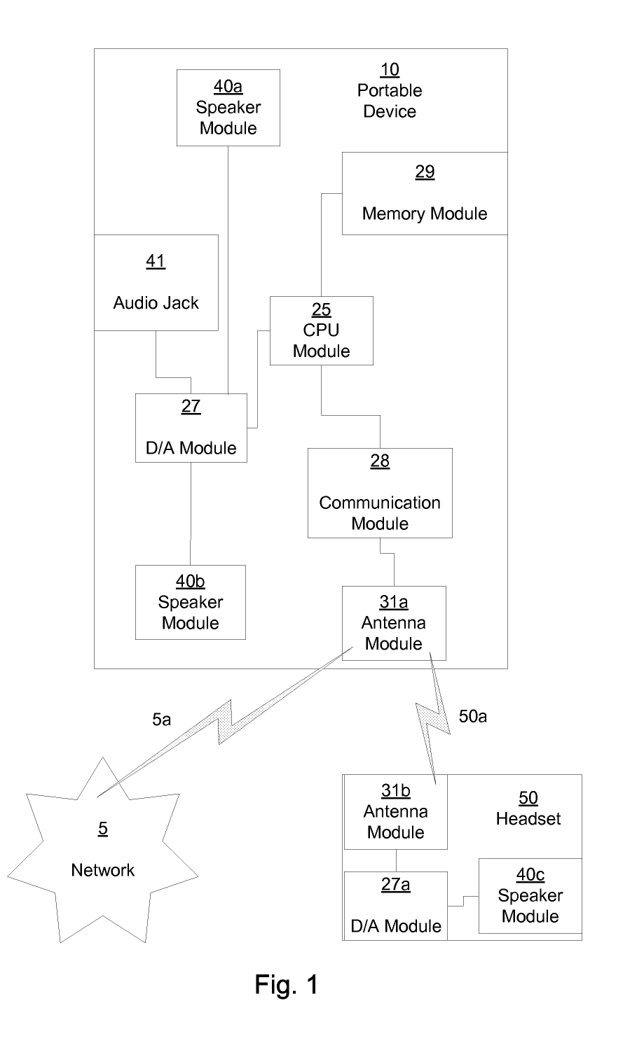

Turning to FIG. 1, an illustrative portable device 10 is depicted. The portable device 10 includes a CPU module 25 in communication with a communication module 28 that may be coupled to an antenna module 31a. If the portable device includes the antenna module 31a, the portable device 10 may be in communication with a network 5 via a communication link 5a. Naturally, the communication module 28 can be configured to couple to the network 5 in other manners such as through wires in a known manner.

The CPU module 25 is also in communication with a memory module 29, which may be a combination of any desirable memory type including volatile and non-volatile memory, fixed and removable memory, as well as random and sequentially accessed memory. As is known, software applications may be stored on the memory module 29 and the CPU module 25 may use the software applications to generate audio output that can be provided to the digital to analog (D/A) module 27. The D/A module 27 takes digital version of the audio output and converts it into an analog version that can be played on a speaker or otherwise provided to some other audio hardware output. The D/A module 27 may further include amplifiers that are capable of adjusting the gain on the audio output in response to signals received from the CPU module 25 so as to allow a user to control the output volume. In an alternative embodiment, an amplifier circuit (not shown) separate from the D/A module may be controlled by signals received from the CPU module 25 so that users can adjust the volume in a desired manner. In either case, it is expected that the hardware adjusting the volume will be capable provide a number of discrete gain levels that will vary depending on the hardware capabilities.

As depicted, the D/A module 27 can provide signals to one or more speaker modules such as speaker modules 40a and 40b. For a telephone call, if the portable device 10 is so configured, it may be sufficient to provide audio output to a single speaker. However, for playing television or video, the use of multiple speakers so as to provide a more complete range of audio reproduction may be beneficial. Furthermore, two separate speaker modules (such as speaker modules 40a and 40b) can be used to provide a stereo sound from the portable device.

The D/A module 27 may also provide audio output to an audio jack 41, which may be configured as a stereo adaptor commonly used for interfacing with headphones and earphones. As is known, the audio jack 41 may be provided in a number of different shapes and sizes and configurations.

In addition to using the on-board D/A module 27, which may include multiple circuits for different hardware outputs such as the audio jack 41 and the speaker modules 40a, 40b, one or more digital outs (not shown) may be connected to the communication module so that a digital version of the sound may be transmitted and converted to analog in a another device, such as home stereo, car stereo or the like. Furthermore, while the use of conventional headphones is fairly common, some individual may prefer to eliminate the wires and use a wireless method of digitally transmitting sound from the portable device to a headset 50 by transmitting signals between antenna module 31a and antenna module 31b. The headset 50 may include a D/A module 27a that converts the digital representations of the sound into an analog version that may be reproduced by the speaker module 40c of the headset 50. As can be appreciated, such a configuration may also include a microphone so that sounds made by the user may be captured and transmitted to the portable device via the antenna module 31b. In such a configuration the D/A module 27a may also include the ability to convert analog signals to digital signals. If the signals are being provided in a digital manner, the signals may include a gain level signal so as to aid in setting the volume observed by the user. It should be noted that while not shown, as can be appreciated by a person of skill in the art, the portable device 10 and the headset 50 are envisioned to include a power source such as a recharge battery in a known manner.

As discussed above, the memory module 29 may include software applications for use in generating audio output. The memory module 29 may also store audio in a digital manner (the audio may be encoded as desired). Alternatively, media may be streamed from the network via communication channel 5a and temporarily stored in the memory module 29 before being converted into audio output by the CPU module 25 (and any required software applications).

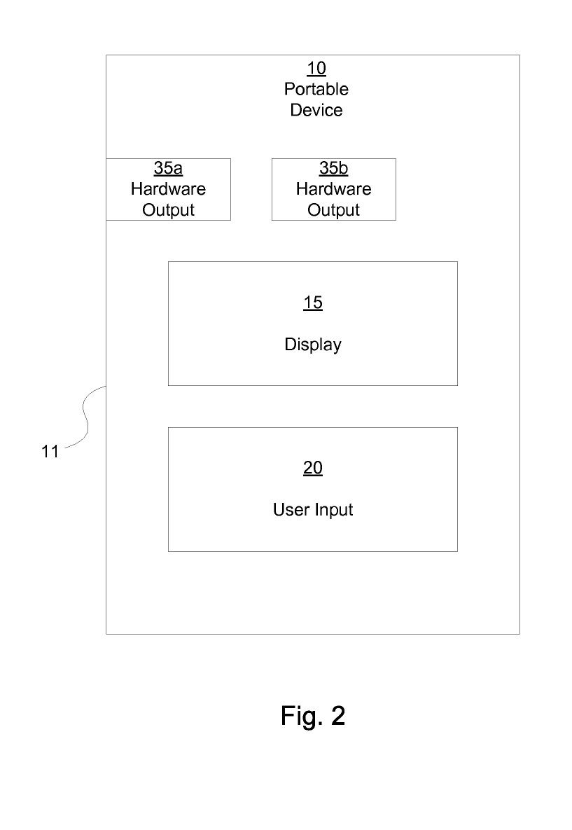

FIG. 2 illustrates a schematic representation of an embodiment of a portable device 10. The portable device 10 includes a housing 11 on which a display 15 and a user input 20 are provided. The display 15 may be any desirable type of display such as, without limitation, an LCD display. The user input 20 may include a number of input keys, a touch pad, a scroll wheel, a joystick, or any other desirable input device, alone or in combination. As can be appreciated, when a user adjusts the volume with the user input 20, a graphical representation of the volume may be provided on the display 15. The graphic depiction allows a user to receive visual feedback of the current volume setting and may include a numerical representation of the volume.

The hardware outputs 35a and 35b, which are two different hardware components used for providing audio such as a speaker, a headphone jack and a digital out, provide two different methods of generating or aiding in the audible reproduction of sound. In an embodiment, a user may switch between the two different hardware outputs by adjusting a switch, either in hardware or software. In an alternative embodiment, the switching may take place automatically and be caused by the user using one of the hardware outputs which has a higher priority than the other hardware output. For example, plugging a connector into a headphone jack may cause the portable device 10 to automatically begin providing audio output to the headphone jack.

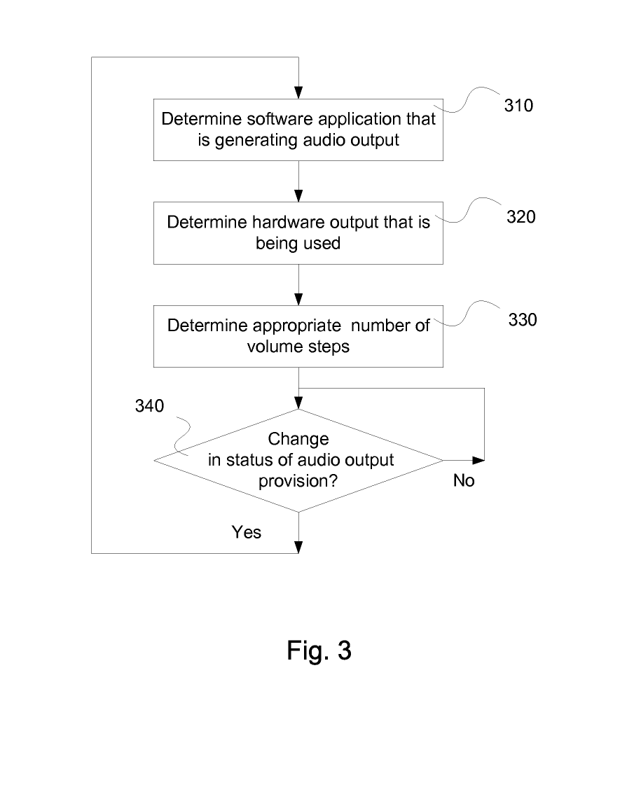

Once audio reproduction begins (e.g., a software application and a hardware output are selected), the method depicted in FIG. 3 may be used. First in step 310, a determination that a software application from a list of software applications is being used to generate audio output is made. As can be appreciated, if a single software application is being used for all audio output then this check may be omitted. Numerous methods of initiating this determination are possible, for example, a check to see if any software application is being used to generate sound may be done on a periodic basis. In an alternative embodiment, using the CPU module 25 (FIG. 1) to provide audio output may trigger the determination. Next in step 320, a determination of which audio hardware output is being used is made. Then in step 330, a determination of the appropriate number of volume steps is determined. This may allow for an automatic update of the graphical display of the number of volume. For example, if the number of steps changes from 5-steps to 20-steps, a volume of one on the 5-step scale could be equivalent to a volume of four on the 20-step scale. Naturally, changes from more steps (such as the number of volume steps associated with music playback) to fewer steps (such as associated with telephone calls) could round off to the nearest step. For example, an eighteen on a twenty volume step scale could be a seven on a seven point volume scale.

In step 340, a check is made to see whether the status of how the audio output is being provided has changed. If no change has been made, then step 340 repeats. If a change is made, then step 310 may be repeated.

It should be noted that variations of the depicted steps are contemplated. For example, the check in step 340 may determine that a hardware change has been made and the next check may be to determine what hardware output is being used without determining the software application that is generating audio output. Furthermore, variations in order of steps may also be made and additional steps may be added as desired.

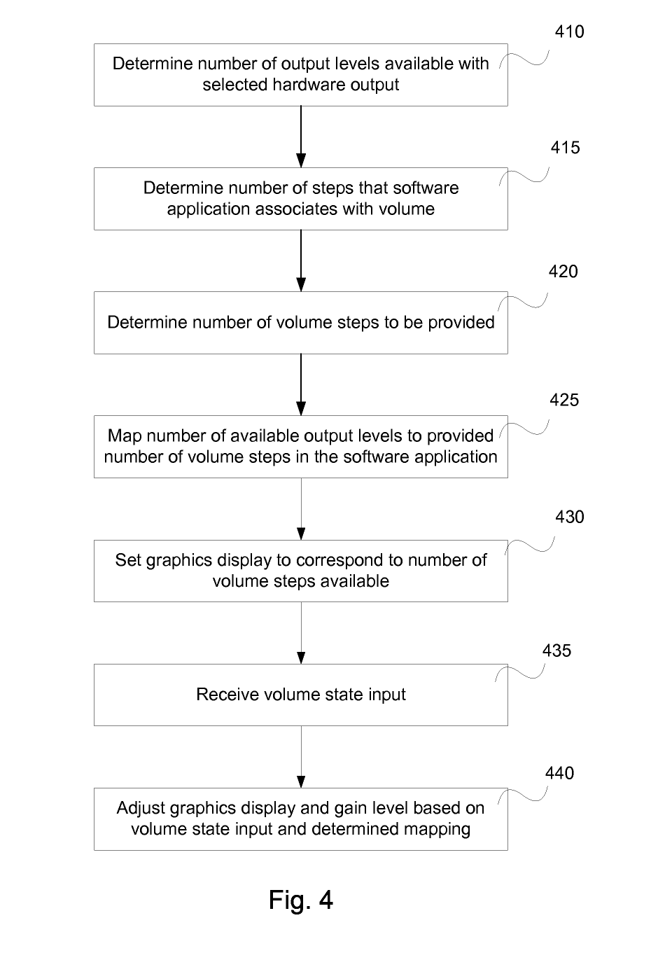

The determination of the appropriate number of volume steps as provided in step 330 may be accomplished with the process depicted in FIG. 4. First in step 410, a determination of the number of steps available with the selected hardware output is made. While certain hardware outputs may have a discrete number of gain levels associated with them, other hardware outputs may have a substantially continuously variable gain level associated with them. Thus, the determination in step 410 may generate a wide range of values. It should be noted that if a large number of steps are possible, the number of steps available may be configured so that each step provides a perceptible change in volume.

Then in step 415, a check is made as to the number of volume steps associated with the currently utilized software application. This number typically will be set based on user preferences and therefore may be adjustable by the user. Next in step 420, a determination of the number of volume steps to be provided can be made. As can be appreciated, the available number of gain levels that the hardware output can provide is the upper limit on the number of volume steps if a change in the volume is going to have any effect.

Once the number of volume steps is determined, in step 425, the number of volume steps that going to be used is mapped to the output levels of the selected hardware output. This can be a 1-1 mapping if both numbers are the same. This can also be some type of mapping with a ratio such as 1-3 and may even include a varying ratio. Next in step 430, the graphics display is set to correspond to the number of volume steps available. It should be noted that no visual depiction of the change in graphic is necessary at the time of setting the graphics display to the new scale—the next time a user adjusts the volume the change can be appreciated and displayed. Thus, step 430 may provide a means for preparing for an expected user-caused volume change.

In step 435, a volume state update is received. This can be caused by a change in the volume or it may simply be a check on the current volume state. Then in step 440, the graphics display is adjusted based on the volume state and the determined mapping between the software application and the hardware output gain levels available.

As can be appreciated from FIGS. 3 and 4, therefore, a user can switch between software applications and/or hardware outputs and the number of volume steps that are associated with the particular combination can be automatically adjusted. This provides a simplified way for the user to change the volume with a single interface that automatically adjusts to how the user is using the portable device.

For example, if a user was listening to music and received a phone call, the user could adjust the volume among a range of seven different volume levels. Once the call was complete, the user could continue to listen to music, which may have been automatically paused by the incoming call, and the change in software (and/or hardware) would allow the user to select one of twenty different volume levels.

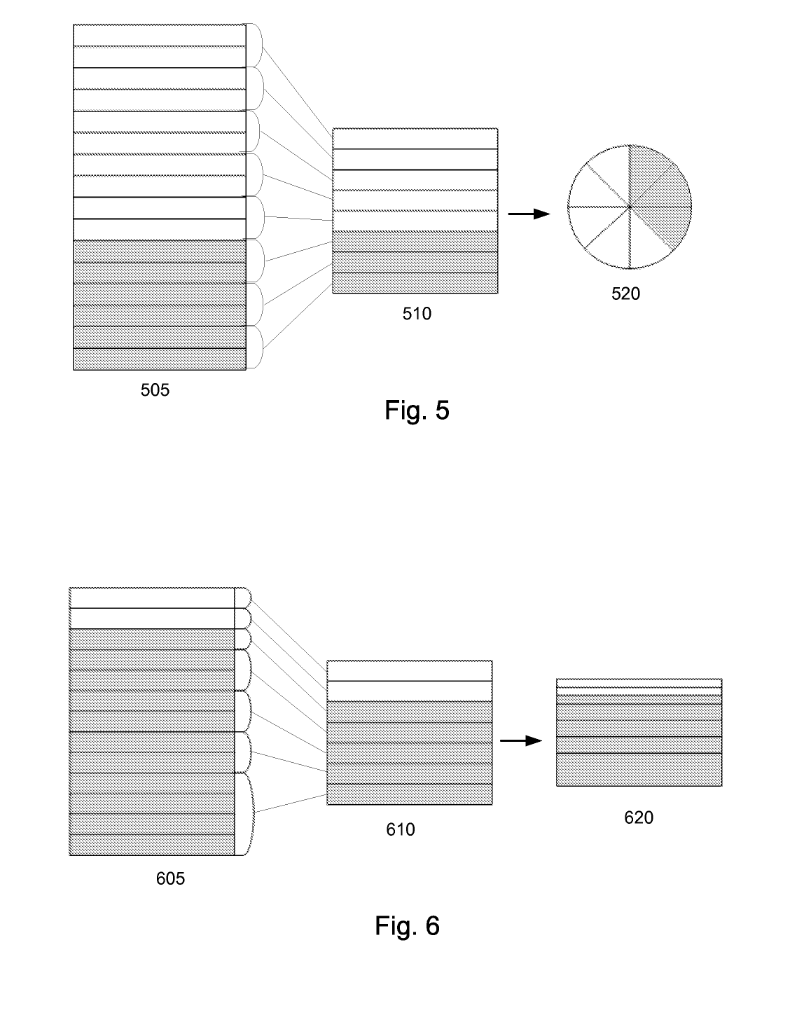

FIGS. 5 and 6 illustrate potential mappings between the hardware output gain levels, the software application volume steps and the graphical display. In FIG. 5, hardware output gain level 505 represent the number of gain levels that are available for the hardware output being used. Volume steps 510 represent the number of volume steps that are deemed appropriate and graphical display 520 represents the number of steps shown on a graphical display as being available to the user. Thus, as depicted in FIG. 5, each incremental volume step in software represents a two-step gain change in the gain level steps 505. The change in volume is depicted on the display 15 with graphic 520, which may provide a linear representation of the number of volume steps available.

FIG. 6 illustrates a mapping between thirteen gain levels steps 605 in the hardware output to seven volume steps 610 in the software application. However, the mapping is not linear and four gain levels steps 605 correspond to one volume step 610. Interestingly, as depicted, the final three gain levels steps are mapped in a 1-1 correspondence with the final volume steps 610. The graphical representation 620 of the volume may also include a non-linear arrangement. As can be appreciated, this allows the initial volume steps to be shown as significant volume changes while later volume steps are shown as being less significant.

As can be appreciated from FIGS. 5 and 6, variations are possible. In an embodiment, a mapping could be non-linear with respect to the number of gain levels in the hardware output compared to the number of volume steps while the graphic display could be linear. In an alternative embodiment, a mapping could be linear between the number of gain levels and the number of volume steps while the graphic display could be non-linear. In other words, the number of gain levels may not correspond in a linear fashion to the number of volume steps. Furthermore, the graphical depiction of the volume may not correspond in a linear manner to either the number of gain levels steps or the number of volume steps.

Other factors may also be used to set the number of steps available. For example, for low bit-rate media, a lesser number of steps may be appropriate. However, for high bit-rate media, a greater number of volume steps may be appropriate.

The present invention has been described in terms of preferred and illustrative embodiments thereof. It should be noted that variation in the disclosed embodiments are contemplated. For example, unless otherwise noted, combinations of features from one or more embodiments may be combined with features of one or more other embodiments. Numerous other embodiments, modifications and variations within the scope and spirit of the appended claims will occur to persons of ordinary skill in the art from a review of this disclosure.

1. A method comprising:
(a) determining a first software application is being used to generate an audio output;
(b) determining a first hardware output is being used to provide audio output, the first hardware output being one of a plurality of hardware outputs; and
(c) automatically adjusting a number of volume steps available to the user based on the use of first software application and the first hardware output.

2. The method of claim 1, wherein the software application is a first software application selected from a list of a plurality of software applications and the adjusting in (c) is based on which one of the plurality of software applications is generating the audio output.

3. The method of claim 1, wherein the determining in (c) comprises:
(i) determining a bit-rate of an encoded audio file being used to generate the audio output; and
(ii) adjusting the number of volume available based on the determined bit-rate.

4. The method of claim 1, further comprising:
(d) in response to a user input, modifying the audio output volume based on the adjusted number of volume steps.

5. The method of claim 4, wherein the modifying in (d) comprises:
(i) adjusting a signal provided by a digital to analog module based on the change in volume; and
(ii) adjusting a graphic on a display so as to represent the change in volume.

6. The method of claim 1, further comprising:
(d) determining a second software application is generating audio output; and
(e) automatically adjusting the number of volume steps available to the user based on the audio output of the second software application.

7. The method of claim 6, further comprising:
(f) in response to the determination that the second software application is generating audio output in (d), determining that a second hardware output is being used to provide audio output, wherein the adjusting in (e) is also based on the determining that the second hardware output is being used.

8. The method of claim 1, wherein the adjusting the number of steps (c) comprises adjusting the number of steps provided in a graphical user interface.

9. The method of claim 1, further comprising:
(d) determining that a second hardware output is being used to provide audio output; and
(e) automatically adjusting the number of volume steps available to the user based on the use of first software application and the second hardware output.

10. An apparatus, comprising:
a housing;
a display mounted on the housing
a user input on the housing;
a digital-to-analog module mounted in the housing;
a first and a second audio hardware output on the housing;
a processor mounted in the housing, the processor in communication with the digital-to-analog module;
a memory module, the memory module configured to store media and software applications and including instructions for causing the processor to:
(a) determine a first software application is being used to generate audio output, the first software application being one of a plurality of software applications;
(b) determine a first hardware output is being used to provide audio output, the first hardware output being one of a plurality of hardware outputs; and
(c) determine a number of volume steps that are available to the user automatically based on the first software application and the first hardware output.

11. The apparatus of claim 10, wherein the memory module further includes instructions for causing the processor to:
(d) configure a graphical user interface to correspond to the determined number of volume steps in (c).

12. The apparatus of claim 10, wherein the memory module further includes instructions for causing the processor to:
(d) determine that a second hardware output is being used to provide audio output, the second hardware output being another of the plurality of hardware outputs; and
(e) adjust the number of volume steps that are available to the user automatically based on the first software application and the second hardware output.

13. The apparatus of claim 12, further including a third audio hardware output, the third audio output comprising a transmitter for digitally transmitting audio output.

14. The apparatus of claim 10, wherein the memory module further includes instructions for causing the processor to:
(d) determine a second software application is being used to generate audio output, the second software application being one of a plurality of software applications; and
(e) adjust the number of volume steps that are available to the user automatically based on the second software application and the first hardware output.

15. The apparatus of claim 10, wherein the instructions in the memory module for causing the processor to make the determination in (a) comprise:
(i) determine that the first software application and a second application are available to generate audio output; and
(ii) determine that the first software application is actively generating audio output.

16. The apparatus of claim 10, further comprising a transceiver supported by the housing and configured to provide wireless access to a network.

17. A portable media device, comprising:
a housing with a user input;
a display mounted on the housing;
a transceiver module mounted in the housing;
a digital-to-analog module mounted in the housing;
a plurality of hardware outputs supported by the housing;
a memory module including a first and second software application; and
a CPU module configured to automatically adjust a number of volume steps associated with the digital to analog module based on the software application and the audio hardware output that is active.

18. The portable media device of claim 17, wherein the plurality of hardware outputs include a speaker module and at least one hardware output selected from the list consisting of a headphone jack and a transmitter.

19. The portable media device of claim 17, wherein the CPU module is configured to adjust the number of volume steps in response to a change in status of activity of the audio hardware output.

20. The portable media device of claim 17, wherein at least one of the plurality of hardware outputs is coupled to the digital-to-analog module.

21. The portable media device of claim 17, wherein the CPU module is further configured to adjust the number of steps based on a type of media being provided by the software application.
